(19) United States
(12) Patent Application Publication
(10) Pub. No.: US 2002/0007965 A1
(43) Pub. Date: Jan. 24, 2002

(54) MODULE TAPE WITH MODULES FOR DUAL-MODE DATA CARRIERS

(75) Inventors: THOMAS RIENER, GRAZ (AT); PETER SCHMALLEGGER, GRAZ (AT)

Correspondence Address: CORPORATE PATENT COUNSEL, US PHILIPS CORPORATION, 580 WHITE PLAINS ROAD, TARRYTOWN, NY, 10591

(73) Assignee: U.S. Philips Corporation

(21) Appl. No.: 09/248,533

(22) Filed: Feb. 11, 1999

(30) Foreign Application Priority Data
Feb. 17, 1998 (EP) 98890042.9
Feb. 17, 1998 (EP) 98890041.1

(51) Int. Cl. H05K 1/16

(52) U.S. Cl. 174/261; 174/260

(57) ABSTRACT

In a module tape (1) comprising modules (2) and comprising a carrier layer (19) to which a plurality of contact-bound-mode module contact zones (9, 10, 11) are attached at the location of a first layer side (20) and to which a plurality of contactless-mode module contact zones (14, 15) are attached at the location of a second layer side (22), the contactless-mode module contact zones (14, 15) are formed by conductor zones deposited on the carrier layer (19) by means of a printing method.

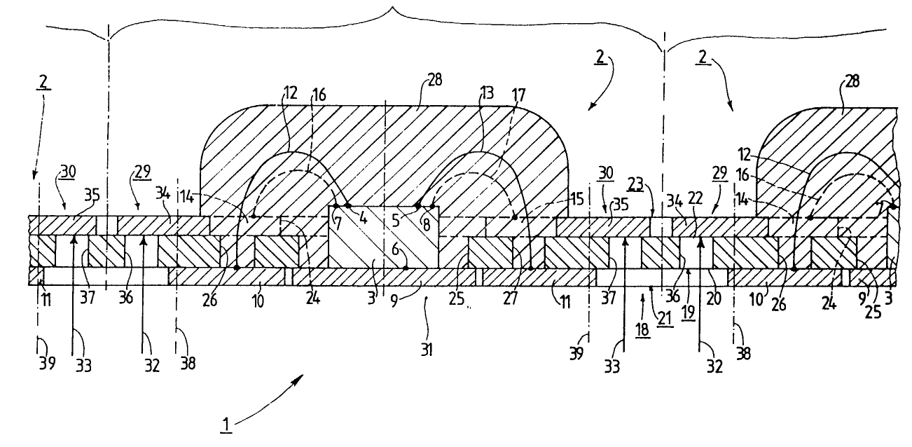

The invention relates to a module tape comprising a plurality of modules each intended for use in a dual-mode data carrier and each including a chip, which data carrier can be operated in a contact-bound mode and in a contactless mode and has contact-bound-mode terminals and contactless-mode terminals, of which the contact-bound-mode terminals are connected to contact-bound-mode module contact zones and the contactless-mode terminals are connected to contactless-mode module contact zones in an electrically conductive manner, and comprising a carrier layer of an electrically insulating material to which the contact-bound-mode module contact zones are attached at the location of a first layer side of the carrier layer, and to which the contactless-mode module contact zones are attached at the location of a second layer side of the carrier layer.

Such a module tape of the type defined in the opening paragraph is known among experts. In the known module tape both the contact-bound-mode module contact zones, which are connected to the carrier layer at the location of a first layer side, and the contactless-mode module contact zones, which are connected to the carrier layer at the location of a second layer side of the carrier layer, are each formed by means of a copper conductor layer. These two conductor layers have been attached to the carrier layer of an electrically insulating material by means of a lamination method during a lamination process, both the carrier layer and the two copper layers being subjected to a punching process prior to the lamination process, in which punching process not only the required openings and recesses are formed but, first and foremost, also contact-bound-mode module contact zones as well as the contactless-mode module contact zones. Punching-out and laminating are comparatively expensive processes, which make the manufacture of the known module tape more expensive. Another drawback is the use of copper conductor layers because copper is a comparatively expensive material.

It is an object of the invention to preclude the afore-mentioned problems and to provide an improved module tape which, in comparison with the known module tape, has the advantage that it can be manufactured more simply and more cheaply.

According to the invention, in order to achieve object with a module tape of the type defined in the opening paragraph, the contactless-mode module contact zones are formed by conductor zones deposited on the carrier layer by means of a printing method. The measures in accordance with the invention make it possible to achieve a comparatively simple and comparatively cheap production of a module tape in accordance with the invention since it is not necessary to punch out a copper conductor layer or conductor foil for the production of the contactless-mode module contact zones because the contactless-mode module contact zones can be manufactured very simply by means of a printing method during a printing process. Moreover, the materials used for forming the contactless-mode module contact zones in such a printing method are cheaper than copper, which is also favorable for the production of a module tape in accordance with the invention at minimal cost.

For a module tape in accordance with the invention having the characteristic features defined in the independent claim 1 it has proved to be very advantageous if, in addition, the measures defined in the dependent claim 2 are taken. This is advantageous for the reason that the well-known advantages of a screen-printing method now also work out for the manufacture of a module tape in accordance with the invention.

For a module tape in accordance with the invention having the characteristic features defined in the independent claim 1 it has proved to be very advantageous if, in addition, the measures defined in the dependent claim 3 are taken. In this way, the known advantages of the use of electrically conductive materials suitable for use in a printing method, such as conductive silver paste, are also utilized in a favorable manner in the production of a module tape in accordance with the invention. It is to be noted that the measures defined in the dependent claim 3 can also be applied advantageously to a module tape in accordance with the invention having the characteristic features defined in the dependent claim 2.

The aforementioned aspects as well as further aspects will be apparent from the example of an embodiment described hereinafter and will be elucidated with reference to this example.

The invention will be described in more detail with reference to an example of an embodiment which is shown in the drawing but to which the invention is not limited.

The FIGURE is a diagrammatical longitudinal view of a module tape in accordance with an embodiment of the invention, the parts of the module tape being shown to an exaggerated scale in a direction transverse to the plane of the tape for the clarity of the drawing.

The FIGURE shows a part of a module tape 1 in a first embodiment of the invention. The module tape 1 comprises a plurality of modules 2, of which only three modules 2 are shown in the FIGURE and of which only one module 2 is shown completely. In the present case each module 2 is intended for use in a dual-mode data carrier. Such a dual-mode data carrier can be a so-called dual-interface chip card, which comprises a plurality of electrically accessible transmission contacts and an inductively accessible transmission coil, data communication via the transmission contacts being possible in a contact-bound mode and data communication via the transmission coil being possible in a contactless mode.

Each module 2 of the module tape 1 includes a chip 3, which in know manner is an integrated device, which comprises for example a microcomputer and at least one memory which cooperates with the microcomputer. Each chip 3 can operate in a contact-bound mode and in a contactless mode. For this purpose, each chip 3 has a given number of contact-bound-mode terminals 4, 5 and 6, for example eight contact-bound-mode terminals 4, 5 and 6 in total, as is shown diagrammatically by a dot in the FIGURE, and has a given number of contactless-mode terminals 7 and 8, for example two contactless-mode terminals 7 and 8 in total, as is also shown diagrammatically by a dot in the FIGURE.

The contact-bound-mode terminals 4, 5 and 6 of each chip 3 are electrically connected to contact-bound-mode module contact zones 9, 10 and 10. In the present case a contactless-mode terminal 6, which is formed by the bottom surface of the chip, is connected directly to the contact-bound-mode module contact zone 9. The other seven contact-bound-mode terminals 4 and 5 are each connected to a contact-bound-mode module contact zone, 10 and 11 respectively, via a so-called bonding wire, 12 and 13 respectively.

The two contactless-mode terminals 7 and 8 of each chip 3 are each electrically connected to a contactless-mode module contact zone, 14 and 15 respectively, each via a further bonding wire, 16 and 17 respectively.

The module tape 1 comprises a layer configuration 18 in the form of a tape, which configuration basically comprises three layers. The layer configuration 18 is made up of a central carrier layer 19, of a first conductor layer 21 attached to the carrier layer 19 at the location of a first layer side 20 of the carrier layer 19, and of a second conductor layer 23 attached to the carrier layer 19 at the location of a second layer side 20 of the carrier layer 19. The carrier layer 19 consists of an insulating material, preferably a plastic, namely a so-called epoxy resin, and in the present case has a thickness in the range between 60 and 100 μm, as is customary. In the present case the first conductor layer 21 consists of copper and in the present case it has a thickness of approximately 50 μm, as is customary. The second conductor layer 23 consists of a stabilized conductive silver paste, which in the present case is or has been formed by depositing a conductive silver paste on the carrier layer 19 by means of a screen-printing method. In the present case the second conductor layer 23 also has a thickness of approximately 50 μm but can alternatively have a smaller thickness. The carrier layer 19 is attached to the first conductor layer 21 by a lamination method in a lamination process.

However, it is to be noted that both conductor layers 21 and 23 may consist of copper and may each have a thickness of approximately 50 μm. Such a layer configuration 18 is manufactured by a lamination method in a lamination process.

The contact-bound-mode module contact zones 9, 10 and 11 for each module 2 are formed by means of the first conductor layer 21. These contact-bound-mode module contact zones 9, 10 and 11 are obtained in that the first conductor layer 21 is subjected to a punching process prior to the lamination process for joining it to the carrier layer 19. Instead of a punching process an etching process can be used.

The contactless-mode module contact zones 14 and 15 are realized by means of the second conductor layer 23. These contactless-mode module contact zones 14 and 15 are realized by means of a printing method, i.e. a screen-printing method, in a printing process. In this printing process one recess 24 per module 2 is formed in the second conductor layer 23 to accommodate the chip 3 of a module.1

As can be seen in the FIGURE, the carrier layer 19 also has a recess 25 per module 2 to accommodate the chip 3 of a module 2. Furthermore, the carrier layer 19 has two holes 26 and 27 per module, through which holes the boding wires 12 and 13 of each module 2 are passed. All the recesses 25 and all the holes 26 and 27 are formed in the carrier layer 19 in a punching process prior to the lamination process.

After the lamination process has been carried out in order to connect the contact-bound-mode module contact zones 9, 10 and 11 to the carrier layer 19 and after the printing process has been carried out in order to connect the contactless-mode module contact zones 14 and 15 to the carrier layer 19 the intermediate product thus obtained is subjected to an electroplating process in a so-called electroplating bath, in which both the contact-bound-mode module contact zones 9, 10 and 11 and the contactless-mode module contact zones 14 and 15 are plated, i.e. are provided with one or more thin metal layers. This plating has the advantage that no patina can be formed on the copper module contact zones and that bonding wires can simply be connected to the module contact zones without any problems. Preferably, gold is used for plating but it is also possible to use other materials, for example nickel.

It is to be noted that in each module 2 the chip 3 and the bonding wires 12, 13, 16 and 17 connected to its contact-bound-mode terminals 4 and 5 and its contactless-mode terminals 7 and 8 are accommodated in a protective cap 28. After the chips 3 have been mounted in the module tape 1 and after the boding wires 12, 13, 16 and 17 have been connected to, respectively, the contact-bound-mode module contact zones 10 and 11 and the contactless-mode module contact zones 14 and 15 the caps 28 are formed by molding-in or encapsulation with an electrically non-conductive material, i.e. a synthetic resin.

The module tape 1 advantageously comprises means 29 and 30 to assure electrically conductive access to the contactless-mode module contact zones 14 and 15 for contact elements external to the module tape 1 through the carrier layer 19 via the free space 31 adjacent the first layer side 20 of the carrier layer 19. Such contact elements are represented diagrammatically by arrows 32 and 33 in the FIGURE.

In a particularly simple and advantageous manner the means 29 and 30 in the module tape 1 first of all have contactless-mode extension zones 34 and 35 and secondly have passages 36 and 37 in the carrier layer 19, which passages are arranged so as to be overlapped by the contactless-mode extension zones 34 and 35. The contactless-mode extension zones 34 and 35 are formed by means of the second conductor layer 23, which is advantageously formed in a printing process, each of these contactless-mode extension zones 34 and 35 being integrally connected to, i.e. integrated with, a respective contactless-mode module contact zone 14 or 15 and projecting laterally from the relevant contactless-mode module contact zone 14 or 15.

As can be seen in the FIGURE, the contactless-mode extension zones 34 and 35 and the passages 36 and 37 guarantee in a particularly simple manner that the external contact elements 32 and 33 very simply have electrically conductive access to the contactless-mode module contact zones 14 and 15, which are integral with the contactless-mode extension zones 34 and 35.

Thus, with the module tape 1 it is simply achieved and guaranteed that the contact-bound-mode module contact zones 9, 10 and 11 as well as the contactless-mode module contact zones 14 and 15 are accessible for external contact elements, i.e. also for test probes, from the free space 31 adjacent or adjoining the first layer side 20 of the carrier layer 19. This has the advantage that a test device for testing the operation of each module 2 or chip 3 attached to the module tape 1 can be brought into contact with the relevant module contact zones via the free space 31, so that testing via the contact-bound-mode module contact zones 9, 10 and 11 as well as via the contactless-mode module contact zones 14 and 15 is possible in a single test process. Moreover, this yields the advantage that during separation of each module 2 from the module tape 1, which is possible for example by means of a cutting process or punching process as indicated by the dash-dot lines 38 and 39 in the FIGURE, the means 29 and 30 can be separated from each module 2, as a result of which the means 29 and 30 left as module tape scrap cannot have any adverse effect on a module 2.

Owing to the afore-mentioned fact that the second conductor layer 23 and, consequently, the contactless-mode module contact zones 14 and 15 formed by means of the second conductor layer 23 as well as the contactless-mode extension zones 34 and 35, which are integrally connected to these contactless-mode module contact zones 14 and 15, have been manufactured in a printing process by a screen-printing method using a conductive silver paste, the great advantage is obtained that the module tape 1 can be manufactured at comparatively low cost because, in comparison with a second conductor layer 23 consisting of copper, a second conductor layer 23 consisting of stabilized conductive silver paste can be manufactured more cheaply since conductive silver paste is cheaper than copper and since a printing process for the formation of contact zones is cheaper than a punching process for the formation of contact zones. The contact zones of conductive silver paste have a lower mechanical strength than copper contact zones but for the module tape 1 in accordance with the invention this is irrelevant because the contactless-mode module contact zones 14 and 15 of conductive silver paste and the contactless-mode extension zones 34 and 35 which are integral with these contactless-mode module contact zones 14 and 15 are not subjected to any mechanical loads during operation of a module 2.

It is to be noted that the first conductor layer 21 need not necessarily consist of copper but may alternatively consist of another electrically conductive material.

1. A module tape (1)
comprising a plurality of modules (2)
each intended for use in a dual-mode data carrier and each including a chip (3), which data carrier can be operated in a contact-bound mode and in a contactless mode and has contact-bound-mode terminals (4, 5, 6) and contactless-mode terminals (7, 8), of which the contact-bound-mode terminals (4, 5, 6) are connected to contact-bound-mode module contact zones (9, 10, 11) and the contactless-mode terminals (7, 8) are connected to contactless-mode module contact zones (14, 15) in an electrically conductive manner, and comprising a carrier layer (19) of an electrically insulating material
to which the contact-bound-mode module contact zones (9, 10, 11) are attached at the location of a first layer side (20) of the carrier layer (19), and
to which the contactless-mode module contact zones (14, 15) are attached at the location of a second layer side (22) of the carrier layer (19),
characterized in that
the contactless-mode module contact zones (14, 15) are formed by conductor zones deposited on the carrier layer (19) by means of a printing method.

2. A module tape (1) as claimed in claim 1, characterized in that the contactless-mode module contact zones (14, 15) are formed by conductor zones deposited on the carrier layer (19) by means of a screen-printing method.

3. A module tape (1) as claimed in claim 1, characterized in that the contactless-mode module contact zones (14, 15) are formed by conductor zones deposited on the carrier layer (19) by means of a printing method using an electrically conductive material, preferably a conductive silver paste.
